(19) United States
(12) Patent Application Publication
(10) Pub. No.: US 2011/0089505 A1
(43) Pub. Date: Apr. 21, 2011

(54) METHOD FOR MANUFACTURING A SENSOR COMPONENT WITHOUT PASSIVATION, AND A SENSOR COMPONENT

(76) Inventors: Simon Schneider, Reutlingen (DE); Andreas Traub, Ammerbuch (DE); Bernd Jahrsdoerfer, Herleshausen (DE); Holger Rumpf, Reutlingen (DE)

(21) Appl. No.: 12/881,894

(22) Filed: Sep. 14, 2010

(30) Foreign Application Priority Data
Sep. 24, 2009 (DE) 102009044980.9

(51) Int. Cl. H01L 29/84; H01L 21/02

(52) U.S. Cl. 257/417; 438/50; 257/E29.324; 257/E21.002

(57) ABSTRACT

A sensor component and a method for manufacturing a sensor component, in which a sealing passivation of a sensor layer may be dispensed with. For this purpose, the sensor component includes, in particular, a thin film high-pressure sensor, a deformation body and a piezoresistive sensor layer, which is applied to the deformation body, the piezoresistive sensor layer including at least one metal as well as carbon and/or hydrocarbon and terminating the layer structure of the sensor component. Based on the materials used a sealing cover of the sensor layer by a thin film passivation layer may be dispensed with. Additional contact layers for contacting the sensor layer may advantageously also be dispensed with. Contacting may then take place directly on the sensor layer, using a bond wire.

### FIELD OF THE INVENTION

The present invention relates to a manufacturing method for a sensor component and to a sensor component, in particular a thin film high-pressure sensor which is terminated by the sensor layer and thus makes do without a passivation layer, preferably also without a contact layer on the sensor layer. In particular, the sensor component according to the present invention may be used in the automotive industry in vehicles.

### BACKGROUND INFORMATION

In pressure sensors according to the related art, strain gauges are frequently used to measure deformation on the surface of components. Strain gauges are measuring devices for detecting expanding deformations. Even in the case of only slight deformations, they change their electrical resistance, which is used as a measure of deformation in a sensor. Strain gauges are based on a structured sensor layer or a functional layer which is applied to an insulating substrate or an insulator-coated, expandable substrate, using thin film or thick film technology. Pressure sensors based on the principle of strain gauge technology are typically characterized by a cavity or a hollow body which is sealed by a diaphragm-like structure. A medium under pressure causes deflection of the diaphragm and, as a result thereof, expansion of the diaphragm surface, which is typically coated with a functional layer which is similar to the strain gauge. Due to the piezoresistive effect, a deflection of the diaphragm produces a change in the electrical resistance of the functional layer. Methods are known for structuring four such piezoelectric resistors in a meander-like geometry as sheet resistors and interconnecting them to form a Wheatstone bridge. This circuit makes it possible to measure the bridge resistances extremely precisely by supplying a stable supply voltage and tapping the offset voltage at the corresponding measuring points. The k factor, which represents the ratio between the relative change in resistance and the expansion of the functional layer or substrate, is a characteristic parameter in this context.

High-pressure sensors are typically based on a substrate which is manufactured from a high-strength steel alloy and has a metal diaphragm which is reversibly deformable in the measuring pressure range. A sensing element is applied to this steel diaphragm, the sensing element being deposited, for example in the case of metal thin film pressure sensors, using physical vapor deposition (PVD) or chemical vapor deposition (CVD) and structured using methods known from microelectronics, for example a photolithographic etching method.

A sensor layer or functional layer which is particularly advantageous for a precision high-pressure sensor typically has a k factor which is as constant as possible over temperature and pressure and which additionally has a very high stability over its life cycle. NiCrSi-based resistors are particularly good choices in this context, although they have a low k factor value in the range of approximately 2 and therefore tend to have a low offset signal of the Wheatstone bridge circuit. Due to the potential sensitivity of this functional layer toward moisture penetration and mechanical scratching, a silicon nitride passivation is typically used. The mechanical protection function may also be provided by a layer of silicon oxide.

High-pressure sensors based on thin film technology are typically characterized by a layer structure which includes, among other things, a structured piezoresistive metal thin film having a low k factor, such as NiCrSi having a k factor of approximately 2, and a passivation layer as protection against mechanical damage. Without a passivation thin film, great care would have to be taken during the production process to protect sensor elements against scratches. However, such care results in a significant increase in manufacturing costs, due to the use of special tools as well as of fully automatic assembly and handling stations for the sensor elements.

In the automotive industry, high-pressure sensors and the like are used for fuel systems, electrohydraulic brakes and electronic stability programs (ESP). The highest pressures in this context occur in common rail systems for diesel fuels, which may range between 1,500 bar and 2,200 bar, sometimes even above this range, depending on the system. For all safety-relevant applications in the automotive sector, there are quality requirements which do not tolerate a failure rate even in the ppm range. The sensor elements must therefore be handled even without unintentional contact with the piezoresistive functional layer. Scratches and foreign material, in particular in the meander area of the functional layer, may cause the high pressure sensor to fail even after the sensor has been installed in the motor vehicle and must therefore be avoided at all cost.

It is known from the literature that alternative piezoresistive functional layers exist which have a k factor >10. Furthermore, Ni-containing hydrocarbon layers have been identified, which have a low temperature coefficient of resistance and sensitivity in addition to a high k factor. German Patent No. DE 199 54 164 describes hydrocarbon layers of this type. According to the publication by Schultes et al. (G. Schultes, P. Frey, D. Göttel, O. Freitag-Weber, Diam. Rel. Mat. 15 (2206) 80-89), layers of this type may be, in particular, advantageously manufactured by applying a mixture of argon and ethylene/ethane in a sputter chamber and introducing energy by increasing the substrate temperature to approximately 300° C. This may be supported by a substrate bias voltage or, if necessary, by using the highest possible sputtering power.

Moreover, the existence of hard material layers in the form of tribological protective layers have long been known which are preferably implemented by using so-called diamond-like carbon (DLC) layers. These layers provide protection against wear and may be used as a finish for the purpose of avoiding scratches, due for example to mechanical handling or contact with the surface.

### SUMMARY OF THE INVENTION

According to the present invention, a sensor component is provided which includes a deformation body and a piezoresistive sensor layer which is applied to the deformation body. The piezoresistive sensor layer includes at least one metal as well as carbon and/or hydrocarbon and terminates the sensor component or the layer structure of the sensor component in a sealing manner.

Based on the selection of the sensor layer material, a sealing thin film passivation layer on the sensor layer may advantageously be dispensed with. Furthermore, additional contact layers for contacting the sensor layer may advantageously also be dispensed with.

The sensor component may be a thin film high-pressure sensor for pressures in the range of 40 bar to 10,000 bar, in particular for pressures between 100 bar and 3,500 bar.

The deformation body may be a metallic deformation body, including a substrate having a deformable metal diaphragm, an insulating layer being provided between the piezoresistive sensor layer and the metal diaphragm to electrically insulate the deformation layer and the sensor layer from each other.

The selection of the materials of the piezoresistive sensor layer advantageously permits the use of sensor layers having a k factor of 5 to 100, preferably between 10 and 25. The sensor layers may thus be selected to be particularly sensitive toward deformations and may thus detect even the smallest deformations.

The piezoresistive sensor layer preferably includes a carbon layer containing metal clusters, in particular metal clusters in amorphous carbon or metal clusters embedded into a graphite matrix. These structures permit the formation of a particularly hard and piezoresistive sensor layer which simultaneously also minimizes the influence of moisture on the measurement.

The metal clusters may be made of Ni, Au, Pt, Pd, Rh, W, Cr, Co as well as combinations thereof.

The piezoresistive sensor layer may be made solely of at least one metal and carbon/hydrocarbon and have between 30 and 70 at % metal, preferably between 45 and 55 at % metal, even more preferably between 50 and 55 at % metal. In particular, the metal is preferably nickel because the latter particularly effectively influences the properties of the sensor layer, such as the k factor and the temperature coefficient of resistance, offset and sensitivity as well as life cycle stability.

The piezoresistive sensor layer may be formed by strain gauges, preferably by four strain gauges arranged in the form of a Wheatstone bridge.

A method for manufacturing a sensor component is also provided, including the following steps: providing a metallic or ceramic deformation body; depositing an insulating layer on the metallic deformation body; depositing a piezoresistive sensor layer which includes at least one metal as well as carbon and/or hydrocarbon on the insulating layer; terminating the layer system of the sensor component using the piezoresistive sensor layer; and wire bonding for contacting the sensor layer of the sensor component.

During wire bonding, the sensor layer may be contacted directly without any further contact layers. In the method according to the present invention, it is therefore possible to dispense with thin film passivation layers and contact layers, which significantly simplifies the manufacturing process and minimizes the manufacturing costs.

The present invention permits a cost-effective layer structure of a metal diaphragm-based high-pressure sensor which is resistant to mechanical scratching of the highly sensitive meander structure during the manufacturing phase between the electrical premeasurement of the micromechanical sensor component and completion of the overall pressure sensor even without a passivation layer and/or contact layers.

Based on the tribological and piezoresistive properties of the sensor component, the sensor component is greatly suitable, in particular, for strict requirements in the automotive industry, such as in fuel systems of vehicles, electrohydraulic brakes and electronic stability programs (ESP).

### BRIEF DESCRIPTION OF THE DRAWINGS

FIG. 1 shows a high-pressure sensor according to the related art having a thin film passivation layer.

FIG. 2 shows a high-pressure sensor according to the related art having a thin film passivation layer and contact layers.

FIG. 3 shows the interconnection of sensor layers into a high-pressure sensor according to the related art.

FIG. 4 shows an exemplary embodiment of the sensor component according to the present invention.

FIG. 5 shows an exemplary embodiment of the sensor component according to the present invention, having contacting.

### DETAILED DESCRIPTION

The present invention is described in detail below on the basis of the drawings. The exemplary embodiment refers to a thin film high-pressure sensor by way of example but is not limited thereto.

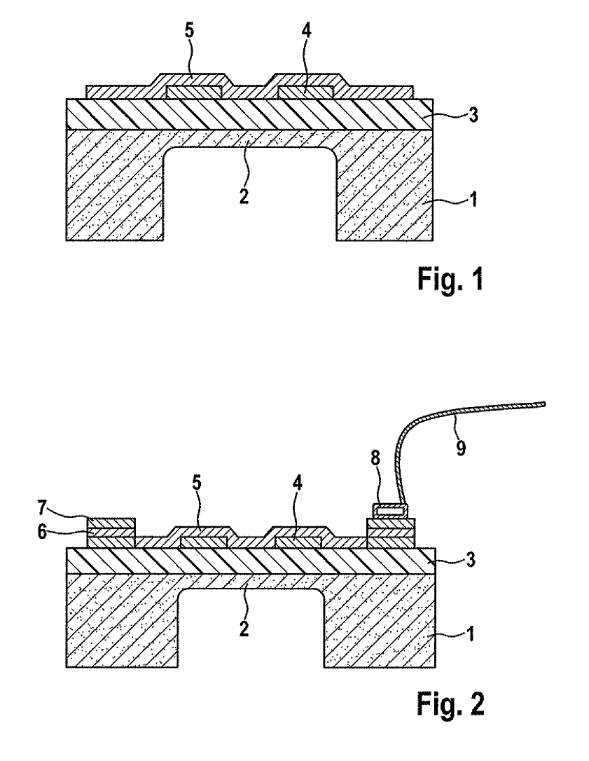

FIG. 1 shows a cross-sectional view of the schematic structure of a high-pressure sensor according to the related art, the high-pressure sensor being based on a metal diaphragm 2. However, a ceramic diaphragm 2 may also be used. The structure is formed as follows: Reference numerals 1 and 2 represent the deformation body, preferably a metal deformation body. This deformation body preferably has a monolithic structure. Reference numeral 1 represents a metal substrate, preferably a steel substrate, which includes a diaphragm 2 which seals a cavity in the deformation body. In FIG. 1, deformation body 1, 2 takes the form of a bridge, diaphragm 2 being the actual bridge section. In the case of a metal diaphragm 2, an electrical insulating layer 3, which prevents a conductive connection between sensor layer 4, hereinafter also referred to as functional layer 4, and substrate 1, is first located on diaphragm 2. Passivation layer 5 in FIG. 1 prevents moisture penetration and mechanical damage to functional layer 4 by unintentional mechanical action or scratching of functional layer 4 during processing and manufacturing steps.

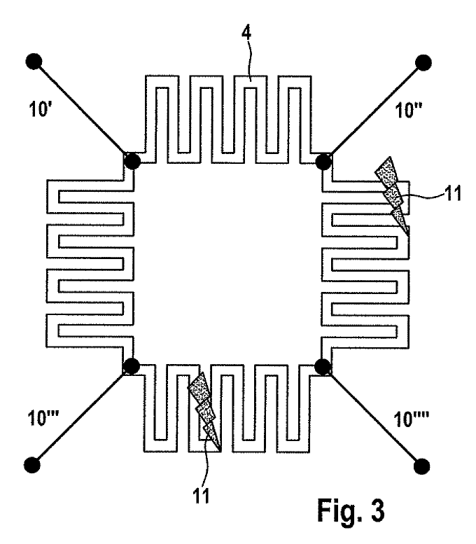

FIG. 2 shows how functional layers 4 are contacted according to the related art. In a preferred, yet not limiting manner, four strain gauges are interconnected to form a Wheatstone bridge (also see FIG. 3). Thin film passivation 5 is applied only to functional layers or strain gauges 4, which are not contacted. To contact the other parts, additional thin films 6, 7 are applied to corresponding functional layers 4 in the form of a contact stack. An adhesion layer 6, made for example of Cr or Al or Pd, is first applied to corresponding functional layer 4. Bonding layer 7, made for example of Au, Al, Ni or FeNi, is then applied to this adhesion layer 6. Reference numerals 8, 9 represent the contacts, including a bonding wire which may be characterized, in particular, by a bonding foot, e.g., a wedge 8, and a bonding loop 9, both being preferably made of Al, Au, Cu or combinations of these elements. Contacting preferably takes place outside this area of diaphragm 2. Non-contacted functional layers 4 are terminated by thin film passivation 5 in FIGS. 1 and 2. The layer structure of contacted functional layers 4 in FIG. 2 are terminated by bonding layer 7, to which wire bond 8, 9 is applied in a contacting manner.

FIG. 3 shows the schematic top view of a metal thin film-based sensor component according to the related art. Sensor layer or functional layer 4 in this case is applied in a meander-shaped structure and connected to form a Wheatstone bridge, which is supplied with a voltage, for example, via contact points 10′ and 10″″. The bridge output voltage is formed between contact points 10″ and 10′″ and represents the output signal of the sensor component, this output voltage depending on the pressure of the applied medium. Potential damage to the soft meander structure is represented as scratch 11. The scratch changes the properties of functional layer 4 and may cause the sensor component to fail.

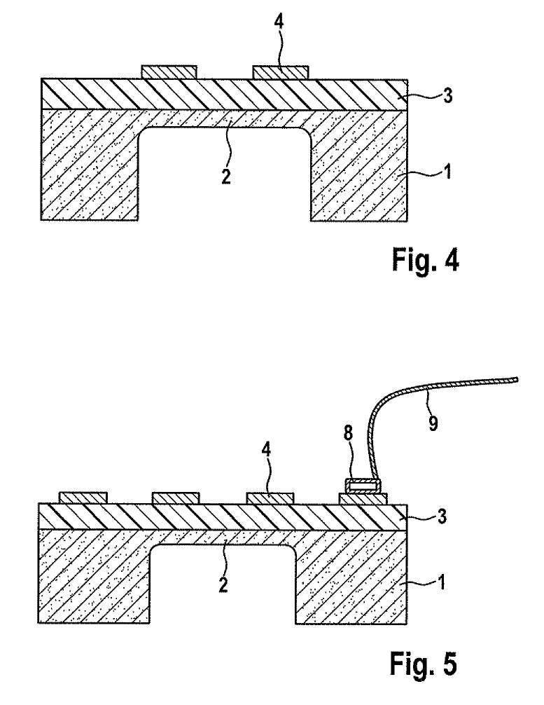

FIG. 4 shows a sensor component according to the present invention, having a metal cluster-based functional layer 4 which is characterized by a high k factor, combined with properties of a hard material layer, and which does not have a further thin film-based passivation layer.

Surprisingly, metal cluster-based functional layer 4 may be contacted directly, e.g., using a suitable wire, for example a 125-μm aluminum heavy wire. This means that a stack of contact layers 6, 7 is no longer needed, but rather functional layer 4 may be contacted directly. This greatly simplifies the layer structure of the sensor component without resulting in additional risk of scratching the surface of the sensor component. Functional layer 4 according to the present invention thus terminates the layer structure of the sensor component. No further thin or thick films are used, and no further layer is needed on functional layer 4. In other words, functional layer 4 seals the layer structure of the sensor component. This is followed only by a wire bonding process for contacting functional layer 4, as shown in FIG. 5. Contacting takes place without contact layers directly on functional layer 4, using a wire which preferably includes a bonding foot 8 and wire 9 itself. Wire 9 and bonding foot 8 are preferably made of Al, Au, Cu or combinations thereof.

The hard material properties of the functional layer material help avoid unwanted scratches and mechanical damage and ensure a more rugged manufacturing process.

An insulating layer 3, usually SiOₓ, is preferably located directly on a metal diaphragm 2. Four strain gauges 4* are situated on insulating layer 3.

These strain gauges form a Wheatstone measuring bridge, which is highly sensitive toward the slightest changes in the resistance of individual meander 4.

An essence of the present invention illustrated here is to replace the metal thin film layer of the related art, e.g., an NiCrSi functional layer 4, with a piezoresistive layer containing metal clusters, which is characterized by a high gain factor of k=5 to 100, preferably between 10 and 25, as well as by special tribological properties.

The carbon layer containing metal clusters may be implemented, in particular, by Ni clusters in amorphous carbon as well as by nickel clusters embedded into a graphite matrix. A layer composition between 30 and 70 atom percent metal, preferably nickel, and 70 to 30 atom percent carbon appears to be suitable. The layer composition may also contain hydrocarbon instead of carbon. In particular, the layer has a composition between 45 and 55 at % metal, preferably nickel, more preferably between 50 and 55 at % metal, preferably nickel, since this makes it possible to implement a layer having hard material properties and piezoresistive properties and which is characterized by low thermal coefficients of sensitivity and electrical resistance as well as adequate protection against moisture.

Moreover, Pt clusters in carbon and potentially a number of additional metal clusters such as Au, Pd, Rh, W, Cr, Co as well as combinations thereof, which may be distinguished from each other with regard to composition, number of clusters and cluster size and are produced by the reactive sputtering method, are also suitable.

The high-pressure sensor according to the present invention is suitable for pressures in the range of 40 bar to 10,000 bar, preferably in the range of 100 bar to 3,500 bar.

The aforementioned materials for functional layer 4 are used here for the first time in a sensor component, utilizing the hard material properties in combination with the piezoresistive functional properties, the materials additionally being enhanced by the high k factor and affording a considerable cost advantage in manufacturing. Thin film passivation may be dispensed with entirely. Contact layers for contacting may also preferably be dispensed with.

What is claimed is:

1. A sensor component comprising:
a deformation body; and
a piezoresistive sensor layer applied to the deformation body, the piezoresistive sensor layer including at least one metal and at least one of carbon and hydrocarbon, the piezoresistive sensor layer terminating the sensor component.

2. The sensor component according to claim 1, wherein the sensor component is a thin film high-pressure sensor for pressures in the range of 40 bar to 10,000 bar.

3. The sensor component according to claim 2, wherein the pressures are between 100 bar and 3,500 bar.

4. The sensor component according to claim 1, wherein the deformation body is a metallic deformation body, including a substrate having a deformable metal diaphragm, and further comprising an insulating layer situated between the piezoresistive sensor layer and the metal diaphragm.

5. The sensor component according to claim 1, wherein the piezoresistive sensor layer has a k factor of 5 to 100.

6. The sensor component according to claim 5, wherein the k factor is between 10 and 25.

7. The sensor component according to claim 1, wherein the piezoresistive sensor layer includes a carbon layer containing metal clusters.

8. The sensor component according to claim 7, wherein the piezoresistive sensor layer includes metal clusters in amorphous carbon or metal clusters embedded in a graphite matrix.

9. The sensor component according to claim 7, wherein the metal clusters are made of Ni, Au, Pt, Pd, Rh, W, Cr, Co, and combinations thereof.

10. The sensor component according claim 1, wherein the piezoresistive sensor layer is made of metal, including nickel and carbon, and has between 30 and 70 at % metal.

11. The sensor component according to claim 10, wherein the piezoresistive sensor layer has between 45 and 55 at % metal.

12. The sensor component according to claim 10, wherein the piezoresistive sensor layer has between 50 and 55 at % metal.

13. The sensor component according to claim 1, wherein the piezoresistive sensor layer is formed by strain gauges.

14. The sensor component according to claim 13, wherein the piezoresistive sensor layer is formed by four strain gauges arranged in the form of a Wheatstone bridge.

15. A method for manufacturing a sensor component, comprising:
providing a deformation body;
depositing a piezoresistive sensor layer which includes at least one metal and at least one of carbon and hydrocarbon on the deformation body;
terminating a layer system of the sensor component using the piezoresistive sensor layer; and
wire bonding for contacting the sensor layer of the sensor component.

16. The method according to claim 15, wherein, during wire bonding, the sensor layer is contacted directly without any further contact layers.
